(19) United States
(12) Patent Application Publication
(10) Pub. No.: US 2023/0219193 A1
(43) Pub. Date: Jul. 13, 2023

(54) METHOD FOR MANUFACTURING COMPONENT MADE OF HARD BRITTLE MATERIAL AND COMPONENT MADE OF HARD BRITTLE MATERIAL

(71) Applicant: SINTOKOGIO, LTD., Nagoya-shi (JP)

(72) Inventors: Norihito SHIBUYA, Nagoya-shi (JP); Hitoshi NISHIJIMA, Nagoya-shi (JP); Kazuyoshi MAEDA, Nagoya-shi (JP); Kazumichi HIBINO, Nagoya-shi (JP); Souichiro NISHIO, Nagoya-shi (JP); Kouichi INOUE, Nagoya-shi (JP)

(73) Assignee: SINTOKOGIO, LTD., Nagoya-shi (JP)

(21) Appl. No.: 18/076,614

(22) Filed: Dec. 7, 2022

(30) Foreign Application Priority Data
Jan. 7, 2022 (JP) 2022-001583

(51) Int. Cl. B24C 1/04

(52) U.S. Cl. CPC B24C 1/04

(57) ABSTRACT

A method for manufacturing a component made of a hard brittle material includes: a step of preparing a base material made of a hard brittle material; and a step of embossing the base material. A protrusion protruding in a first direction and a bottom surface surrounding the protrusion are formed on the base material by the embossing. The bottom surface extends in a plane defined by a second direction intersecting the first direction and a third direction intersecting the first direction and the second direction. The bottom surface and a side surface of the protrusion continuous with the bottom surface satisfy a relationship of z=Ax²−Bx in a cross section defined by the first direction and the second direction when the first direction is represented by z and the second direction is represented by x. A is 0.005 to 0.200 and B is 0.050 to 0.955.

### CROSS-REFERENCE TO RELATED APPLICATION

This application is based on Japanese Patent Application No. 2022-001583 filed with Japan Patent Office on Jan. 7, 2022 and claims the benefit of priority thereto. The entire contents of the application are incorporated herein by reference.

### TECHNICAL FIELD

The present disclosure relates to a method for manufacturing a component made of a hard brittle material and a component made of a hard brittle material.

### BACKGROUND

There is known a processing method of forming an uneven shape on a surface of a base material made of a hard brittle material by blasting. For example, in Japanese Unexamined Patent Application Publication No. 2019-162675, an electrostatic chuck used for manufacturing a semiconductor is manufactured by the above-described processing method.

### SUMMARY

In the component made of the hard brittle material, such as the electrostatic chuck, the protrusions may be worn by repeated use. Since the protrusion formed by the processing method described in Japanese Unexamined Patent Application Publication No. 2019-162675 has a tapered shape tapering toward the tip, the area of the upper surface of the protrusion changes over time. Therefore, the performance of the component made of the hard brittle material can change over time. For example, in the electrostatic chuck, the heat transfer performance and the like may change when the area where the protrusion is in contact with the wafer changes, so that it may be necessary to change the manufacturing conditions at the time of film formation or the like.

The present disclosure describes a method for manufacturing a component made of a hard brittle material and a component made of a hard-brittle material which can suppress changes over time in the performance of the component made of the hard brittle material.

A method for manufacturing a component made of a hard brittle material according to one aspect of the present disclosure includes: a step of preparing a base material made of a hard brittle material; and a step of embossing the base material. A protrusion protruding in a first direction and a bottom surface surrounding the protrusion are formed on the base material by the embossing. The bottom surface extends in a plane defined by a second direction intersecting the first direction and a third direction intersecting the first direction and the second direction. The bottom surface and a side surface of the protrusion continuous with the bottom surface satisfy a relationship of z=Ax²−Bx in a cross section defined by the first direction and the second direction when the first direction is represented by z and the second direction is represented by x. A is 0.005 to 0.200 and B is 0.050 to 0.955.

The bottom surface and the side surface of the protrusion which are formed by the above-mentioned manufacturing method satisfy the above-mentioned relationship. Therefore, a shape in which the protrusion rises sharply in the first direction from the bottom surface can be obtained. That is, the cross-sectional shape of the protrusion orthogonal to the first direction hardly changes depending on the position of the protrusion in the first direction. Therefore, even if the protrusion is worn out, the area of the top surface of the protrusion hardly changes. As a result, changes in the performance of the component made of a hard brittle material over time can be suppressed.

In some embodiments, the step of embossing may include a step of forming a mask pattern on the base material and a step of blasting the base material on which the mask pattern is formed. In this case, a portion of the base material which is not covered with the mask pattern is processed by the brittle fracture principle by the shot media colliding with the portion. As a result, the base material can be subjected to embossing.

In some embodiments, a constituent material of the mask pattern may be an acrylic urethane resin. In this case, the mask pattern is not easily worn out by the blasting, so that the shape of the mask pattern can be maintained during the blasting. Therefore, since the possibility that the same portion of the base material continues to be covered by the mask pattern during the blasting increases, the processing accuracy can be improved. As a result, it is possible to more reliably obtain a shape in which the protrusion rises sharply in the first direction from the bottom surface.

In some embodiments, an injection speed of shot media used in the blasting may be 100 meters per second or more. When the injection speed of the shot media increases, the straightness of the shot media is improved. When the injection speed is 100 meters per second or more, the shot media can easily enter the corner portion formed by the bottom surface and the protrusion. Therefore, it is possible to more reliably obtain a shape in which the protrusion rises sharply in the first direction from the bottom surface.

In some embodiments, a particle diameter of shot media used for the blasting may be 38 μm or less. In this case, the shot media can easily enter the corner portion formed by the bottom surface and the protrusion. Therefore, it is possible to more reliably obtain a shape in which the protrusion rises sharply in the first direction from the bottom surface.

A component made of a hard brittle material according to another aspect of the present disclosure includes: a base having a flat plate shape; and a protrusion protruding from one surface of the base in a first direction. The one surface extends in a plane defined by a second direction intersecting the first direction and a third direction intersecting the first direction and the second direction. The one surface and a side surface of the protrusion continuous with the one surface satisfy a relationship of z=Ax²−Bx in a cross section defined by the first direction and the second direction when the first direction is represented by z and the second direction is represented by x. A is 0.005 to 0.200 and B is 0.050 to 0.955.

In the above-mentioned component made of the hard brittle material, the one surface and the side surface of the protrusion satisfy the above-mentioned relationship. Therefore, the component made of the hard brittle material has a shape in which the protrusion rises sharply in the first direction from the one surface. That is, the cross-sectional shape of the protrusion orthogonal to the first direction hardly changes depending on the position of the protrusion in the first direction. Therefore, even if the protrusion is worn out, the area of the top surface of the protrusion hardly changes. As a result, changes in the performance of the component made of a hard brittle material over time can be suppressed.

According to each aspect and each embodiment of the present disclosure, it is possible to suppress changes over time in performance of a component made of a hard brittle material.

### BRIEF DESCRIPTION OF THE DRAWINGS

FIG. 1 is a flowchart of a method for manufacturing a component made of a hard brittle material according to an embodiment.

FIG. 2 is a diagram for explaining a lamination step.

FIG. 3 is a diagram for explaining an exposure step.

FIG. 4 is a diagram for explaining a development step.

FIG. 5 is a diagram schematically showing a blasting device.

FIG. 6 is a diagram for explaining a blasting step.

FIG. 7 is a diagram showing an example of the movement path of a nozzle.

FIG. 8 is a perspective view showing an example of a component made of a hard brittle material manufactured by the method for manufacturing the component made of the hard brittle material shown in FIG. 1.

FIG. 9 is a cross-sectional view taken along the line IX-IX of FIG. 8.

FIG. 10A is a diagram showing a processed shape of Example 1.

FIG. 10B is a diagram showing a processed shape of Comparative Example 1.

FIG. 10C is a diagram showing a processed shape of Comparative Example 2.

### DETAILED DESCRIPTION

In the following, embodiments of the present disclosure will be described in detail with reference to the drawings. In the description of the drawings, the same elements are designated with the same reference signs, and the redundant description will be omitted. In each figure, an XYZ coordinate system may be shown. The Y-axis direction (third direction) is a direction intersecting (orthogonal to) the X-axis direction (second direction) and the Z-axis direction (first direction). The Z-axis direction is a direction intersecting (orthogonal to) the X-axis direction and the Y-axis direction.

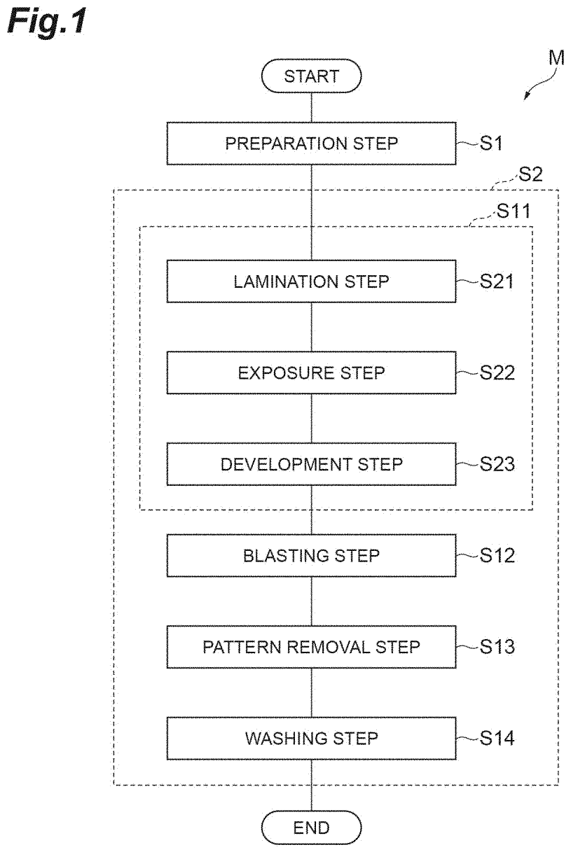

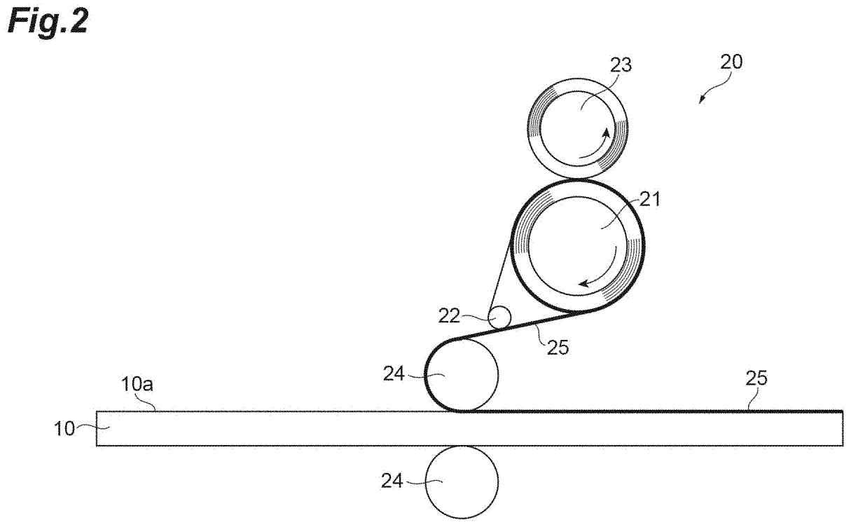

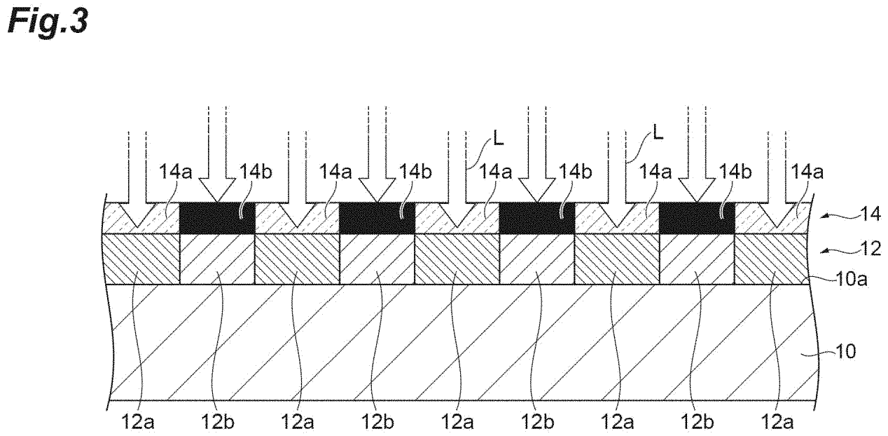

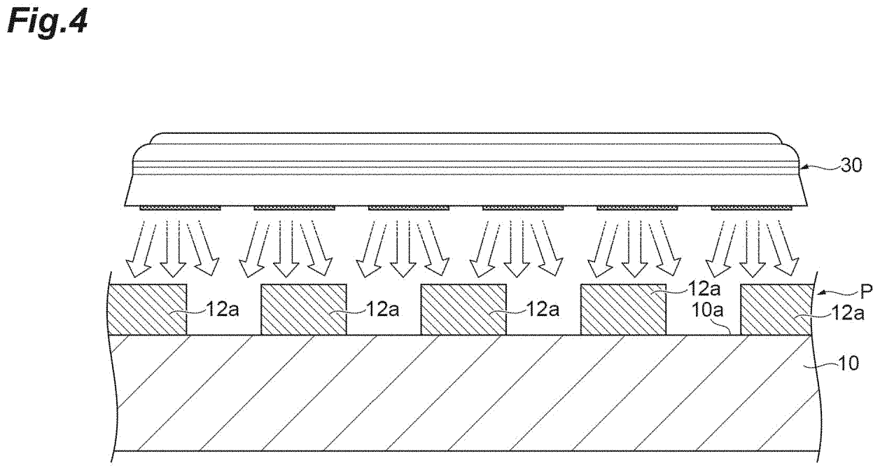

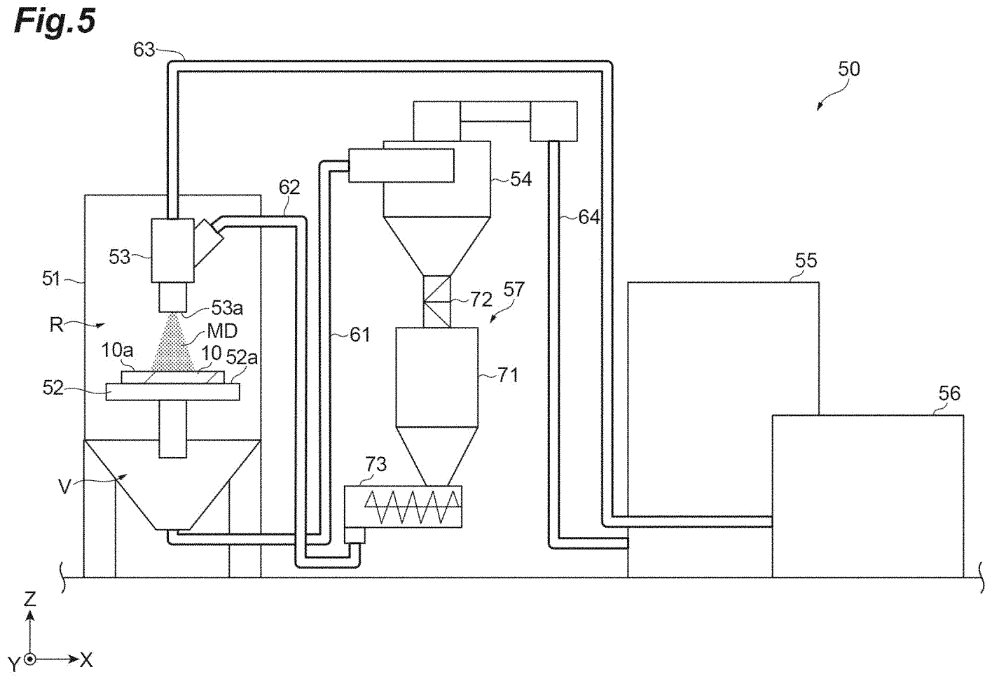

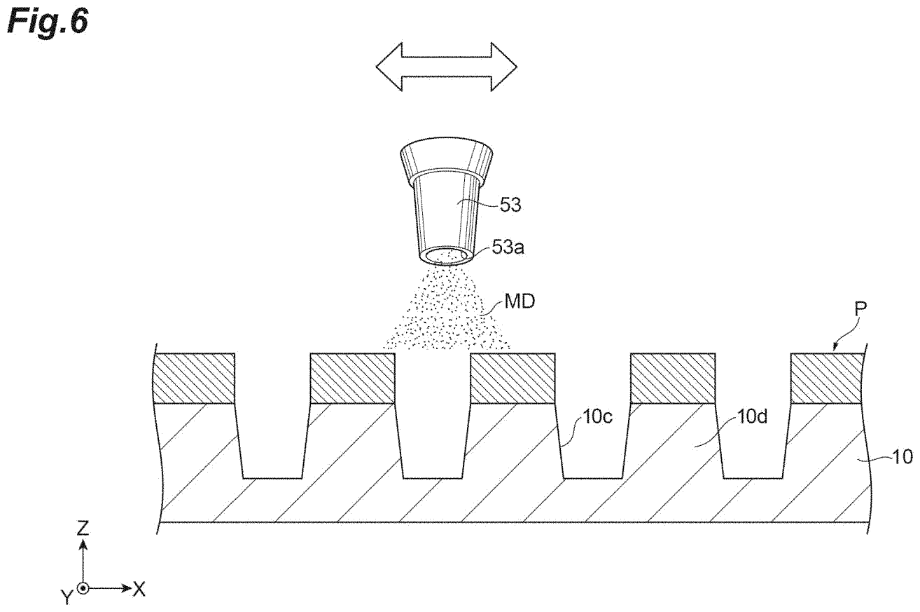

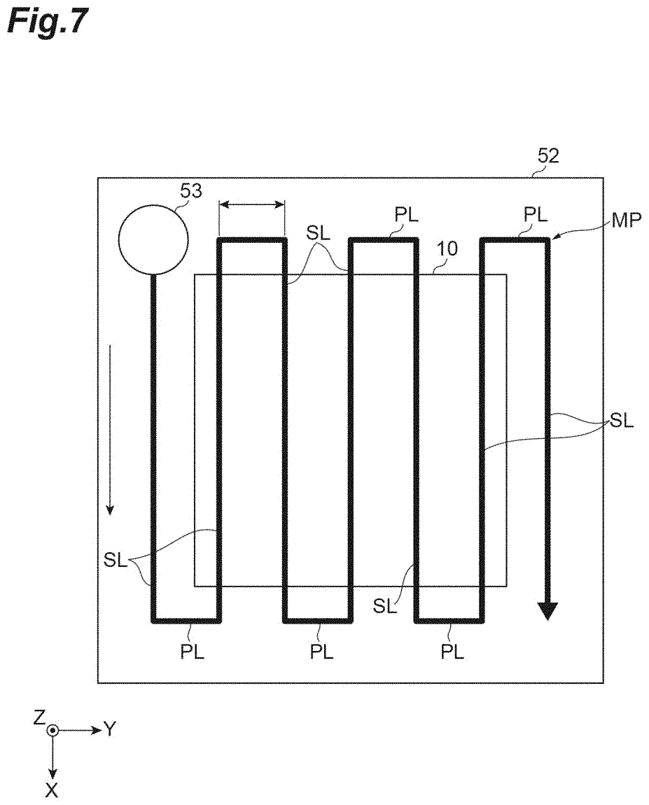

A method for manufacturing a component made of a hard brittle material according to an embodiment will be described with reference to FIGS. 1 to 7. FIG. 1 is a flowchart of a method for manufacturing a component made of a hard brittle material according to an embodiment. FIG. 2 is a diagram for explaining a lamination step. FIG. 3 is a diagram for explaining an exposure step. FIG. 4 is a diagram for explaining a development step. FIG. 5 is a diagram schematically showing a blasting device. FIG. 6 is a diagram for explaining a blasting step. FIG. 7 is a diagram showing an example of the movement path of a nozzle. A manufacturing method M of a component made of a hard brittle material shown in FIG. 1 is a method for forming an uneven shape on a base material. The manufacturing method M includes a preparation step S1 and an embossing step S2.

<Preparation Step S1>

The preparation step S1 is a step of preparing the base material 10. As the base material 10, for example, a substrate having a plate-like shape is prepared. The base material 10 is made of a hard brittle material. Examples of constituent materials of the base material 10 include ceramic materials such as aluminum nitride, alumina, silicon carbide, glass, silicon, sapphire, and gallium oxide. The base material 10 has a surface 10a and a surface 10b. The surface 10b is a surface opposite to the surface 10a.

<Embossing Step S2>

Following the preparation step S1, the embossing step S2 is performed. The embossing step S2 is a step of embossing the base material 10. In the present embodiment, the embossing step S2 includes a pattern forming step S11, a blasting step S12, a pattern removal step S13, and a washing step S14.

<Pattern Forming Step S11>

The pattern forming step S11 is a step of forming a resist pattern P on the base material 10. More specifically, the resist pattern P is formed on the surface 10a of the base material 10. The resist pattern P is a mask pattern defining a portion to be protected in the blasting described later. In the present embodiment, the pattern forming step S11 includes a lamination step S21, an exposure step S22, and a development step S23.

<Lamination Step S21>

The lamination step S21 is a step of forming a resist film 12 on the surface 10a of the base material 10. The resist film 12 is a photosensitive photoresist. For example, a liquid resist or a dry film resist is used to form the resist film 12. As a constituent material (material) of the resist film 12, a material a material that is not easily worn out by the blasting described later is used. Examples of constituent materials of the resist film 12 include urethane resins such as acrylic urethane, polyurethane, and urethane acrylate.

When the resist film 12 is formed using a liquid resist, the liquid resist is uniformly applied to the surface 10a using a coater. Examples of the coater include a spin coater, a roll coater, a die coater, and a bar coater. Alternatively, the liquid resist may be uniformly applied to the surface 10a by screen printing. Thereafter, the applied liquid resist is dried to form the resist film 12 on the surface 10a.

As shown in FIG. 2, when the resist film 12 is formed using a dry film resist 25, a laminating device 20 is used. The laminating device 20 includes a supply roller 21, a peeling roller 22, a collection roller 23, and a crimping roller 24. The supply roller 21 holds the dry film resist 25, and is configured to supply the dry film resist 25. As the dry film resist 25, for example, a dry film resist (type: MS7100) manufactured by Mitsubishi Paper Mills Ltd. is used. A protective film is provided on one surface of the dry film resist 25, and a carrier film is provided on the other surface of the dry film resist 25. An example of a constituent material of the protective film is polyethylene. An example of a constituent material of the carrier film is polyethylene terephthalate (PET).

The peeling roller 22 is a roller for peeling the protective film from the dry film resist 25. The collection roller 23 is a roller for collecting the protective film peeled off by the peeling roller 22. The crimping roller 24 is a roller for crimping the dry film resist 25 to the surface 10a of the base material 10. In the present embodiment, a pair of crimping rollers 24 are used.

The protective film of the dry film resist 25 supplied from the supply roller 21 is peeled off by the peeling roller 22 and collected by the collection roller 23. Then, while the surface of the dry film resist 25 from which the protective film has been removed is superposed on the surface 10a of the base material 10, the base material 10 and the dry film resist 25 pass between the pair of crimping rollers 24. As a result, the dry film resist 25 is attached to the surface 10a. At this time, the dry film resist 25 is attached by moving the base material 10 or the crimping roller 24 along the surface 10a at a constant speed in one direction. The protective film may be manually peeled off by an operator.

The crimping roller 24 may be a heating roller including a heating element. In this case, the crimping roller 24 crimps the dry film resist 25 to the surface 10a while heating the dry film resist 25. The base material 10 itself may be heated in advance by a constant temperature chamber or the like. The heating temperature is appropriately set within a range of, for example, 30° C. to 80° C. If the heating temperature is too high, the adhesion between the base material 10 and the dry film resist 25 becomes too high. As a result, there is a possibility that the dry film resist 25 is not fully developed at the time of development, resulting in a residual film. If the heating temperature is too low, the adhesion between the base material 10 and the dry film resist 25 becomes too low. As a result, there is a possibility that the dry film resist 25 in the portion to be protected after development is lost, and a desired pattern cannot be formed. Therefore, the heating temperature can be appropriately selected in consideration of the material of the base material 10, exposure conditions, and development conditions.

As described above, the dry film resist 25 is attached to the surface 10a so that air does not enter between the base material 10 and the dry film resist 25. Then, an excess portion of the dry film resist 25 is cut off along the outer shape of the surface 10a. As a result, the resist film 12 is formed on the surface 10a of the base material 10. Instead of the pair of crimping rollers 24, a table on which the base material 10 is placed and a crimping roller 24 may be used. The operator may manually attach the dry film resist 25 to the base material 10 without using the laminating device 20.

The resist material contained in the dry film resist or the resist solution may be a positive resist material or a negative resist material. The positive resist material is a resist material characterized in that the exposed region 12a of the resist film 12 is dissolved and the unexposed region 12b remains. The negative resist material is a resist material characterized in that the unexposed region 12b of the resist film 12 is dissolved and the exposed region 12a remains.

<Exposure Step S22>

Following the lamination step S21, the exposure step S22 is performed. The exposure step S22 is a step of exposing the resist film 12. As shown in FIG. 3, in the exposure step S22, a pattern mask 14 is placed on the resist film 12, and the resist film 12 is irradiated with the energy beam L from the light source of the exposure device through the pattern mask 14. A reference position such as an alignment mark provided in the pattern mask 14 is recognized by image processing or the like, and the pattern mask 14 is placed in a desired position on the resist film 12 using the reference position. When positional accuracy is not required, the pattern mask 14 may be placed by visual observation.

As the pattern mask 14, a negative mask having a region 14a through which the energy beam L passes and a region 14b through which the energy beam L does not pass is used. The pattern mask 14 has a configuration in which a predetermined pattern is formed on, for example, a transparent plate material. Examples of transparent plate materials include glass and film. The pattern has, for example, black color. In the transparent plate material, a region where no pattern is formed corresponds to the region 14a, and a region where a pattern is formed corresponds to the region 14b.

As the energy beam L, for example, visible light or ultraviolet light is used. As the light source for emitting the energy beam L, for example, a light emitting diode (LED) lamp, a mercury lamp, a metal halide lamp, an excimer lamp and a xenon lamp are used. When the dry film resist is an ultraviolet curable resin, an ultraviolet light source (type: BHG-750) manufactured by Cerma Precision Inc. is used as the light source. A rod-shaped lens may be used to enhance the straightness of the energy beam L. In this case, the energy beam L emitted from the light source passes through the rod-shaped lens to be rectified. Further, a mirror may be provided due to dimensional constraints of the exposure device. In this case, the direction of the energy beam L is changed by the mirror.

When the resist film 12 is irradiated with the energy beam L, the pattern of the pattern mask 14 is transferred to the resist film 12. Specifically, since the portion of the resist film 12 covered by the region 14a is irradiated with the energy beam L, the portion is cured to become the exposed region 12a. On the other hand, since the portion of the resist film 12 covered by the region 14b is irradiated with no energy beam L, the portion becomes the unexposed region 12b. The energy beam L is emitted, for example, in a dark room. If the amount of light is too low, there is a possibility that the resist film 12 is not sufficiently cured in the thickness direction of the resist film 12. In this case, the dimension of the resist film 12 may be largely changed from the design value at the time of development, and a pattern in which the width becomes narrower from the surface of the resist film 12 toward the base material 10 may be formed. The amount of light is defined as the product of the illuminance of the energy beam L and the irradiation time. The amount of light is set as an exposure condition so as to obtain a pattern having a uniform width in the thickness direction of the resist film 12.

The exposure step S22 may be performed manually or may be automated by an exposure device.

<Development Step S23>

Following the exposure step S22, the development step S23 is performed. The development step S23 is a step of developing the pattern transferred to the resist film 12. As shown in FIG. 4, a developing device 30 sprays a developing solution onto the resist film 12. An alkaline aqueous solution is used as the developing solution. The developing solution is obtained, for example, by diluting sodium carbonate, which is an alkaline powder, with water by a desired concentration (for example, 0.3 to 1% by weight). An optimum concentration is appropriately selected depending on the resist film 12. The developing solution may be heated to about 40° C. in order to improve the developing property. The developing solution is pressurized by a pressure pump or the like and is conveyed to the nozzle. Then, the developing solution and compressed air are mixed in the nozzle, and the developing solution is atomized to be sprayed from the nozzle onto the base material 10. The temperature of the compressed air is, for example, about 100° C. The developing solution may be sprayed onto the base material 10 by showering.

The nozzle and the base material 10 are configured to be relatively movable. The base material 10 may be fixed, and the nozzle may be movable. The nozzle may be fixed, and the base material 10 may be movable. The nozzle and the base material 10 may be configured to move independently. The developing solution is uniformly sprayed onto the resist film 12 by the nozzle and the base material 10 moving relative to each other at a constant speed. As a result, uniform development can be realized over the entire resist film 12. By spraying the developing solution onto the resist film 12, the unexposed region 12b is selectively removed and the exposed region 12a remains. Thereafter, the developed resist film 12 (exposed region 12a) is washed with water, for example, so that the reaction of the developing solution is stopped. Then, the resist film 12 is dried by air blow or the like. As described above, the resist pattern P having a fine and uniform pattern is formed on the base material 10.

If the amount of the developing solution sprayed is insufficient, the unexposed area 12b may remain as a residual film. On the other hand, if the amount of developing solution sprayed is excessive, the resist pattern P may be peeled off. A development condition capable of avoiding the peeling of the resist pattern P while suppressing the residual film is set. For example, the relative moving speed between the nozzle and the base material 10 is a factor that determines the amount of developing solution to be sprayed. Therefore, the moving speed may be set as the development condition so as to obtain a desired resist pattern P.

The development step S23 may be performed manually or may be automated by the developing device 30.

<Blasting Step S12>

Following the pattern forming step S11, the blasting step S12 is performed. The blasting step S12 is performed by, for example, a blasting device 50 shown in FIG. 5. The blasting device 50 is a suction type blasting device. The blasting device 50 includes a container 51, a table 52, a nozzle 53, a classification mechanism 54, a dust collector 55, a compressor 56, and a supply device 57. The container 51 defines a processing chamber R therein. The lower portion of the container 51 defines a collection space V having a tapered shape whose width becomes narrower downward. An opening for supplying the shot media MD collected in the collection space V to the classification mechanism 54 is formed at the bottom of the container 51. One end of a collection tube 61 is connected to the opening. The other end of the collection tube 61 is connected to the classification mechanism 54.

The table 52 is a table on which the base material 10 is placed. The table 52 is provided in the processing chamber R. The table 52 has a placement surface 52a. The base material 10 is placed and fixed on the placement surface 52a. The placement surface 52a may be an suction surface for sucking and fixing the base material 10.

The nozzle 53 injects the shot media MD toward the surface 10a of the base material 10. The nozzle 53 is provided in the processing chamber R and disposed above the table 52. An injection port 53a is provided at the tip end of the nozzle 53. The nozzle 53 is provided in the processing chamber R so that the injection port 53a faces the placement surface 52a of the table 52. The nozzle 53 is a suction type nozzle. One end of a hose 62 and one end of a hose 63 are connected to the nozzle 53. The nozzle 53 injects the shot media MD supplied from the supply device 57 via the hose 62 together with the compressed air supplied from the compressor 56 via the hose 63 as a gas-solid two phase flow.

At least one of the table 52 and the nozzle 53 is configured such that the table 52 and the nozzle 53 can move relative to each other by a moving mechanism (not shown). As the moving mechanism, for example, an X-Y stage is used.

The classification mechanism 54 is a mechanism for sucking the particles including the shot media MD injected from the nozzle 53 to the base material 10, and separating the particles into the reusable shot media MD and dust (a general term for the cutting powder of the base material 10 generated by the blasting, the shot media MD having a size that cannot be reused, and the like) which is a particle other than the reusable shot media MD. The classification mechanism 54 is, for example, a cyclone classifier. One end of a tube 64 is connected to the classification mechanism 54. The other end of the tube 64 is connected to the dust collector 55.

The dust collector 55 is a device for collecting fragments of the shot media MD and cutting powder of the base material 10. The dust collector 55 suctions the tube 64 to generate air flow from the opening of the container 51 toward the dust collector 55 through the collection tube 61, the classification mechanism 54, and the tube 64. By this air flow, the particles including the used shot media MD collected in the collection space V of the container 51 are conveyed to the classification mechanism 54. By the operation of the dust collector 55, a swirling air flow is generated inside the classification mechanism 54, and the particles (reusable shot media MD) having a heavy mass fall downward. On the other hand, the particles (dust) having a light mass are sucked into the dust collector 55 through the tube 64. The dust sucked by the dust collector 55 is captured using a filter.

The supply device 57 is a device for supplying the shot media MD to the nozzle 53. The supply device 57 is provided below the classification mechanism 54. The supply device 57 includes a hopper 71, a valve 72, and a conveying mechanism 73. The hopper 71 is a container for storing the shot media MD. The hopper 71 has a shape in which the area of the cross-section decreases downward. The cross-sectional shape of the hopper 71 may be circular or polygonal.

The valve 72 is provided at a connecting portion between the classification mechanism 54 and the hopper 71, and has a function of communicating the space in the classification mechanism 54 with the space in the hopper 71 or isolating the space in the classification mechanism 54 from the space in the hopper 71. The valve 72 is, for example, a double damper. When a predetermined amount of the reusable shot media MD is deposited on the lower part of the classification mechanism 54, the valve 72 is opened so that the predetermined amount of the shot media MD falls into the hopper 71. Thereafter, when the valve 72 is closed, the space in the classification mechanism 54 is isolated from the space in the hopper 71. The timing for opening and closing the valve 72 may be controlled by the amount of the deposited reusable shot media MD or by time. The valve 72 may be omitted.

The conveying mechanism 73 takes out a fixed amount of the shot media MD from the hopper 71, and supplies the taken-out shot media MD to the nozzle 53 via the hose 62. The fixed amount of the shot media MD among the shot media MD stored in the hopper 71 is supplied to the nozzle 53 by rotation of the conveying screw in the conveying mechanism 73.

A direct pressure type blasting device may be used in place of the blasting device 50.

In the blasting step S12, various processing conditions are set in combination according to the material of the base material 10, the shape of the recess and protrusions, and the like. For example, the following processing conditions are used. As the shot media MD, for example, shot media having a hardness equal to or higher than that of the base material 10 and having a particle size (average particle diameter) of 5 to 70 μm are used. The injection speed is set at, for example, 80 to 300 m/sec. The injection distance is set to, for example, 5 to 20 times the diameter of the nozzle 53. The injection angle is set to, for example, 75 to 105 degrees.

In the blasting step S12, first, the door of the container 51 is opened, and the base material 10 on which the resist pattern P is formed is placed on the placement surface 52a of the table 52 by the transfer robot. Subsequently, after the operation of the dust collector 55 is started, compressed air is supplied from the compressor 56 to the nozzle 53 via the hose 63. Thereafter, operation of the supply device 57 is started, and the shot media MD are supplied to the nozzle 53 via the hose 62.

As shown in FIGS. 6 and 7, the nozzle 53 moves relative to the table 52 (base material 10) at a constant speed so that the nozzle 53 injects the shot media MD along a movement path MP. The movement path MP has a zigzag shape and includes a plurality of scanning lines SL and a plurality of feed lines PL. That is, the nozzle 53 moves relative to the base material 10 at the constant speed in the X-axis positive direction along the first scanning line SL (scanning line SL at the left end in FIG. 7). Then, the nozzle 53 moves relative to the base material 10 at the constant speed in the Y-axis positive direction along the first feed line PL. Then, the nozzle 53 moves relative to the base material 10 at the constant speed in the X-axis negative direction along the second scanning line SL. Then, the nozzle 53 moves relative to the base material 10 at the constant speed in the Y-axis positive direction along the second feed line PL. By repeating this series of operations, the nozzle 53 injects the shot media MD onto the surface 10a of the base material 10 along the movement path MP. As a result, the shot media MD are uniformly injected over the entire surface 10a of the base material 10. While the nozzle 53 is moving along the movement path MP, the nozzle 53 continues to inject the shot media MD.

Since the shot media MD collide with a portion of the surface 10a which is not covered with the resist pattern P, the portion is processed according to the brittle fracture principle to form a recess 10c. On the other hand, since the shot media MD do not reach the portion of the surface 10a which is covered with the resist pattern P, the portion is not processed and remains as a protrusion 10d.

<Pattern Removal Step S13>

Following the blasting step S12, the pattern removal step S13 is performed. The pattern removal step S13 is a step of removing the resist pattern P from the base material 10. For example, the resist pattern P is removed from the surface 10a of the base material 10 by spraying the peeling liquid from the spray nozzle toward the surface 10a of the base material 10.

<Washing Step S14>

Following the pattern removal step S13, the washing step S14 is performed. The washing step S14 is a step of removing the shot media remaining on the base material 10. The base material 10 is immersed in a cleaning liquid so that the shot media are washed away from the base material 10. Note that the pattern removal step S13 and the washing step S14 may be performed in one step.

As described above, the base material 10 is subjected to an embossing to manufacture a component made of a hard brittle material.

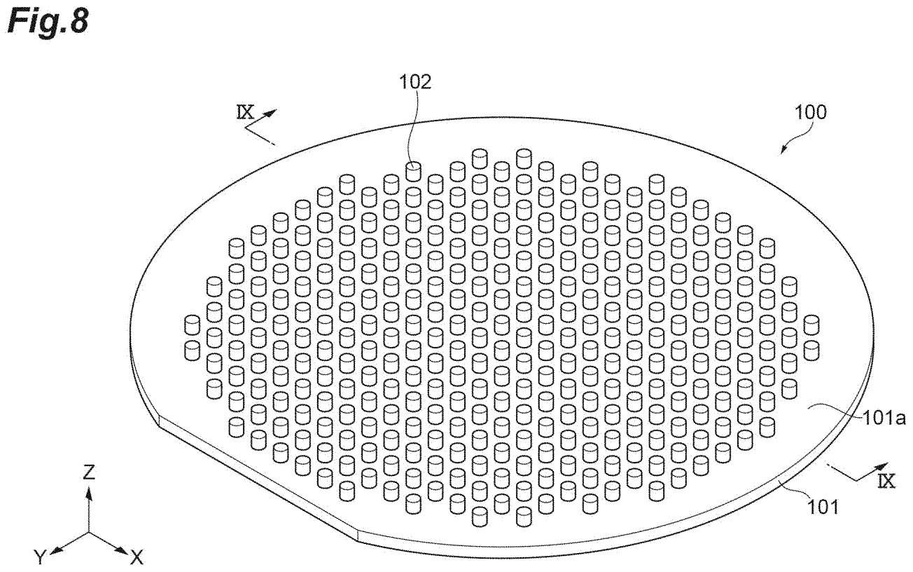

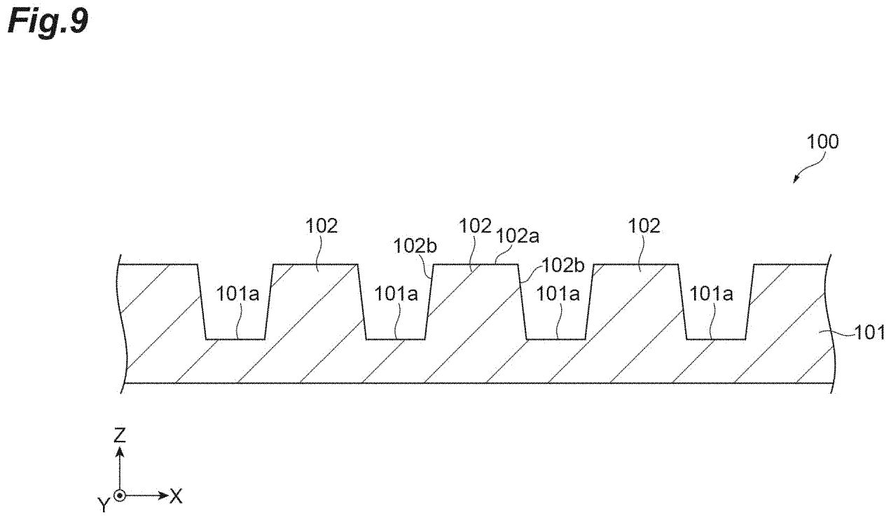

Next, a component made of a hard brittle material manufactured by the manufacturing method M will be described with reference to FIGS. 8 and 9. A component 100 made of a hard brittle material shown in FIGS. 8 and 9 is, for example, an electrostatic chuck. The component 100 includes a base 101 and a plurality of protrusions 102. The base 101 is a flat plate-like portion. The base 101 has a surface 101a (bottom surface, one surface). The surface 101a is a plane substantially parallel to the plane defined by the X-axis direction and the Y-axis direction.

Each protrusion 102 is a columnar portion protruding from the surface 101a in the Z-axis direction. That is, the surface 101a surrounds the protrusion 102. In the present embodiment, each protrusion 102 has a cylindrical shape. The protrusion 102 has a top surface 102a and a side surface 102b. The top surface 102a is a surface that is substantially parallel to surface 101a. When the component 100 is an electrostatic chuck, a semiconductor wafer is placed on the top surface 102a. The side surface 102b is a peripheral surface of the protrusion 102. The side surface 102b is provided between the surface 101a and the top surface 102a, and is connected to the surface 101a and the top surface 102a.

In the cross section defined by the X-axis direction and the Z-axis direction, the surface 101a and the side surface 102b satisfy the relationship of z=Ax²−Bx. Here, z represents a position in the Z-axis direction, and x represents a position in the X-axis direction. A is 0.005 to 0.200, and B is 0.050 to 0.955. In other words, in above-described the cross section, the above relational expression can be obtained by approximating the position z in the Z-axis direction of the shape formed by the surface 101a and the top surface 102a by a quadratic function of the position x in the X-axis direction.

In the component 100 manufactured by the manufacturing method M, the surface 101a and the side surface 102b of the protrusion 102 satisfy the relational expression z=Ax²−Bx. Here, A is 0.005 to 0.200 and B is 0.050 to 0.955. Therefore, a shape in which the protrusion 102 rises sharply in the Z-axis direction from the surface 101a can be obtained. That is, the cross-sectional shape of the protrusion 102 orthogonal to the Z-axis direction hardly changes depending on the position of the protrusion 102 in the Z-axis direction. Therefore, even if the protrusion 102 is worn out, the area of the top surface 102a of the protrusion 102 hardly changes. As a result, changes in the performance of the component 100 over time can be suppressed. For example, in the case where the component 100 is an electrostatic chuck, it is not necessary to change the setting of the film formation conditions even if the protrusion 102 is worn out.

In the above-described manufacturing method M, a portion of the base material 10 which is not covered with the resist pattern P is processed by the brittle fracture principle by the shot media MD colliding with the portion. As a result, the base material 10 can be subjected to embossing.

As a constituent material of the resist pattern P, for example, an acrylic urethane resin is used. Since the acrylic urethane resin has a high elasticity, the acrylic urethane resin can absorb an impact at the time of collision of the shot media MD. Therefore, the resist pattern P is not easily worn out by the blasting, so that the shape of the resist pattern P can be maintained during the blasting. Therefore, since the possibility that the same portion of the base material 10 continues to be covered by the resist pattern P during the blasting increases, the processing accuracy can be improved. As a result, it is possible to more reliably obtain a shape in which the protrusion 102 rises sharply in the Z-axis direction from the surface 101a.

When the injection speed of the shot media MD is low, the straightness of the shot media MD deteriorates, so that there is a possibility that the shot media MD do not sufficiently reach the corner portion formed by the surface 101a and the protrusion 102. In this case, the protrusion 102 has a tapered shape that becomes wider toward the surface 101a. On the other hand, when the injection speed of the shot media MD increases, the straightness of the shot media MD is improved. For example, when the injection speed is 100 meters per second or more, the shot media MD easily enter the corner portion formed by the surface 101a and the protrusion 102. Therefore, it is possible to more reliably obtain a shape in which the protrusion 102 rises sharply in the Z-axis direction from the surface 101a.

When the particle diameter (average particle diameter) of the shot media MD is large, there is a possibility that the shot media MD do not sufficiently reach the corner portion formed by the surface 101a and the protrusion 102. In this case, the protrusion 102 has a tapered shape that becomes wider toward the surface 101a. On the other hand, when the particle diameter of the shot media MD is 38 μm or less, for example, the shot media MD can easily enter the corner portion formed by the surface 101a and the protrusion 102. Therefore, it is possible to more reliably obtain a shape in which the protrusion 102 rises sharply in the Z-axis direction from the surface 101a.

The method for manufacturing a component made of a hard brittle material and the component made of a hard brittle material according to the present disclosure are not limited to the above-described embodiments.

For example, in the lamination step S21, the resist pattern P may be attached to the surface 10a of the base material 10. In this case, the pattern forming step S11 does not have to include the exposure step S22 and the development step S23.

Next, evaluations of the processed shape will be described. In order to evaluate the processed shape, blasting was performed on the base material under several processing conditions.

[Evaluation of Processed Shape Depending on Material of Resist Pattern]

In order to evaluate the influence of the material of the resist pattern P on the processed shape of the base material 10, blasting was performed using resist patterns P of several materials.

(Material of Resist Pattern)

### Example 1

Acrylic urethane resin was used as the material of the resist pattern.

### Comparative Example 1

Acrylic resin was used as the material of the resist pattern.

### Comparative Example 2

Metal was used as the material of the resist pattern.

(Common Processing Conditions)

An aluminum nitride substrate was used as the base material. The design value of the diameter of the protrusion was 500 μm. GC #1200 (manufactured by Sintokogio, Ltd.) was used as the shot media. The injection speed was set at 120 m/sec and the injection angle was set at 90 degrees. The nozzle was repeatedly moved along the movement path MP until the recess formed by the blasting reached a predetermined depth. In Example 1 and Comparative Examples 1 and 2, the thicknesses of the resist patterns before blasting were 50 μm, and the diameters of the resist patterns before blasting were approximately 500 μm.

Table 1 shows the materials of the resist patterns, the thicknesses and diameters of the resist patterns before processing, the thicknesses of the resist patterns after processing, the diameters of the top surfaces of the protrusions, and approximate expressions of the processed shapes of Example 1 and Comparative Examples 1 and 2. The processed shape is a shape of the surface 101a and the side surface 102b in a cross section defined by the X-axis direction and the Z-axis direction. In each approximation expression, z represents a position in the Z-axis direction, and x represents a position in the X-axis direction. The same applies to the following evaluations.

TABLE 1

| | | | COMPARATIVE | COMPARATIVE |
|---|---|---|---|---|
| | | EXAMPLE 1 | EXAMPLE 1 | EXAMPLE 2 |
| MATERIAL OF RESIST PATTERN | | ACRYLIC | ACRYLIC | METAL |
| | | URETHANE | RESIN | |
| | | RESIN | | |
| BEFORE | THICKNESS OF | 50 | 50 | 50 |
| PROCESSING | RESIST PATTERN [μm] | | | |
| | DIAMETER OF | 503 | 501 | 503 |
| | RESIST PATTERN [μm] | | | |
| AFTER | THICKNESS OF | 45 | 10 | 40 |
| PROCESSING | RESIST PATTERN [μm] | | | |
| | DIAMETER OF TOP SURFACE | 498 | 394 | 520 |
| | OF PROTRUSION [μm] | | | |
| | PROCESSED SHAPE | z = 0.1x² − 0.48x | z = 0.004x² − 0.05x | — |
| | (APPROXIMATE EXPRESSION) | | | |

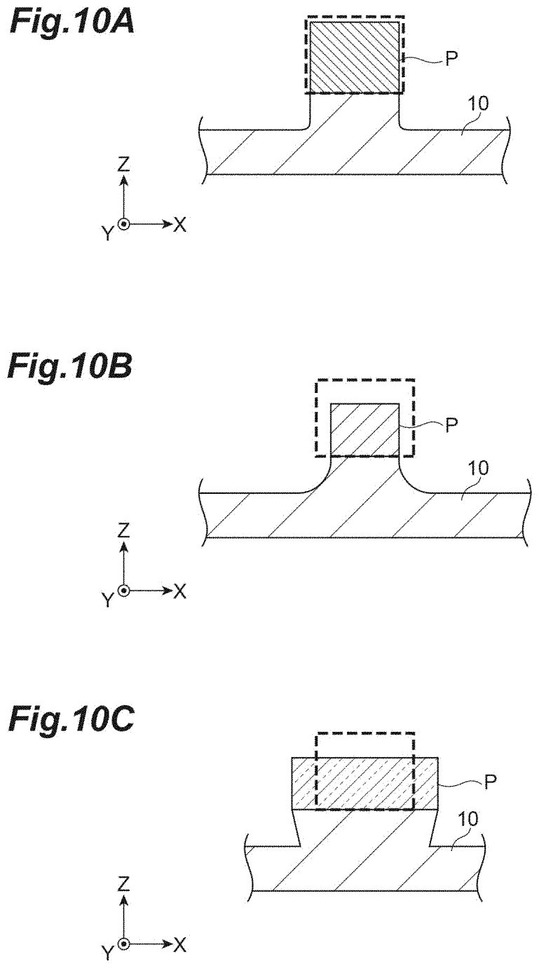

The processed shapes of Example 1 and Comparative Examples 1 and 2 will be described with reference to FIGS. 10A to 10C and Table 1. FIG. 10A is a diagram showing a processed shape of Example 1. FIG. 10B is a diagram showing a processed shape of Comparative Example 1. FIG. 10C is a diagram showing a processed shape of Comparative Example 2. As shown in FIG. 10B, in Comparative Example 1, the resist pattern P was worn by blasting, and its diameter gradually decreased. Therefore, the processed shape was a tapered shape in which the diameter increases from the top surface 102a toward the surface 101a, and the diameter of the top surface of the protrusion was smaller than the design value.

As shown in FIG. 10C, in Comparative Example 2, since the material of the resist pattern P is metal, the resist pattern P has durability against blasting but has ductility. Therefore, as the collision of the shot media MD was repeated, the resist pattern P extended along the surface 10a. As a result, the processed shape was a reverse tapered shape in which the diameter decreases from the top surface 102a toward the surface 101a, and the diameter of the top surface of the protrusion was larger than the design value.

On the other hand, as shown in FIG. 10A, in Example 1, since the resist pattern P is not easily worn out by the blasting, the shape of the resist pattern P was maintained during the blasting. Therefore, the processed shape was a shape in which the protrusion 102 rises sharply in the Z-axis direction from the surface 101a, and the diameter of the top surface of the protrusion was substantially equal to the design value.

[Evaluation of Processed Shape Depending on Injection Speed]

In order to evaluate the influence of the injection speed on the processed shape of the base material 10, blasting was performed at several injection speeds. The type of blasting machine was selected to achieve a predetermined injection rate.

(Injection Speed and Blasting Device)

### Example 2

A suction type blasting device was used and the injection speed was set at 100 m/sec.

### Example 3

A suction type blasting device was used and the injection speed was set at 130 m/sec.

### Example 4

A direct pressure type blasting device was used and the injection speed was set at 150 m/sec.

### Example 5

A direct pressure type blasting device was used and the injection speed was set at 200 m/sec.

### Comparative Example 3

A suction type blasting device was used and the injection speed was set at 70 m/sec.

(Common Processing Conditions)

An aluminum nitride substrate was used as the base material. The design value of the diameter of the protrusion was 500 μm. Acrylic urethane resin was used as the material of the resist pattern. GC #1200 (manufactured by Sintokogio, Ltd.) was used as the shot media. The injection angle was set at 90 degrees. The nozzle was repeatedly moved along the movement path MP until the recess formed by the blasting reached a predetermined depth. In Examples 2 to 5 and Comparative Example 3, the thicknesses of the resist patterns before blasting were 50 μm, and the diameters of the resist patterns before blasting were approximately 500 μm.

Table 2 shows the injection speed, the number of times of processing, the thicknesses and diameters of the resist patterns before processing, the thicknesses of the resist patterns after processing, the diameters of the top surfaces of the protrusions, and approximate expressions of the processed shapes of Examples 2 to 5 and Comparative Example 3.

TABLE 2

| | | COMPARATIVE | | | | |
|---|---|---|---|---|---|---|
| | | EXAMPLE 3 | EXAMPLE 2 | EXAMPLE 3 | EXAMPLE 4 | EXAMPLE 5 |
| | INJECTION SPEED | 70 | 100 | 130 | 150 | 200 |
| | [m/s] | (SUCTION TYPE) | (SUCTION TYPE) | (SUCTION TYPE) | (DIRECT | (DIRECT |
| | | | | | PRESSURE TYPE) | PRESSURE TYPE) |
| | NUMBER OF TIMES | 5 | 4 | 3 | 2 | 1 |
| | OF PROCESSING | | | | | |
| BEFORE | THICKNESS OF | 50 | 50 | 50 | 50 | 50 |
| PROCESSING | RESIST PATTERN [μm] | | | | | |
| | DIAMETER OF | 501 | 499 | 502 | 505 | 501 |
| | RESIST PATTERN [μm] | | | | | |
| AFTER | THICKNESS OF | 48 | 45 | 45 | 43 | 40 |
| PROCESSING | RESIST PATTERN [μm] | | | | | |
| | DIAMETER OF TOP | 500 | 495 | 498 | 501 | 495 |
| | SURFACE OF | | | | | |
| | PROTRUSION [μm] | | | | | |
| | PROCESSED SHAPE | z = 0.005x² − 0.04x | z = 0.005x² − 0.05x | z = 0.089x² − 0.23x | z = 0.194x² − 0.8x | z = 0.2x² − 0.95x |
| | (APPROXIMATE | | | | | |
| | EXPRESSION) | | | | | |

In Comparative Example 3, since the injection speed of the shot media MD was low, it is considered that the straightness of the shot media MD deteriorated, and the shot media MD did not sufficiently reach the corner portion formed by the surface 101a and the protrusion 102. For this reason, the processed shape was a tapered shape in which the diameter increases from the top surface 102a toward the surface 101a. On the other hand, in Examples 2 to 5, since the injection speed of the shot media MD was high, it is considered that the straightness of the shot media MD was improved and the shot media MD sufficiently reached the corner portion formed by the surface 101a and the protrusion 102. Therefore, the processed shape was a shape in which the protrusion 102 rises sharply in the Z-axis direction from the surface 101a.

[Evaluation of Processed Shape Depending on Particle Size of Shot Media]

In order to evaluate the influence of the particle size of the shot media on the processed shape of the base material 10, blasting was performed using the shot media of several particle sizes.

(Particle Size of Shot Media)

### Example 6

Shot media having a particle size of #400 were used. This particle size corresponds to an average particle size of 38 μm.

### Example 7

Shot media having a particle size of #600 were used. This particle size corresponds to an average particle size of 25 μm.

### Example 8

Shot media having a particle size of #1200 were used. This particle size corresponds to an average particle size of 13 μm.

### Example 9

Shot media having a particle size of #1500 were used. This particle size corresponds to an average particle size of 10 μm.

### Comparative Example 4

Shot media having a particle size of #220 were used. This particle size corresponds to an average particle size of 70 pin.

(Common Processing Conditions)

An aluminum nitride substrate was used as the base material. The design value of the diameter of the protrusion was 500 pin. Acrylic urethane resin was used as the material of the resist pattern. GC (manufactured by Sintokogio, Ltd.) was used as the shot media. The injection speed was set at 120 m/sec and the injection angle was set at 90 degrees. The nozzle was repeatedly moved along the movement path MP until the recess formed by the blasting reached a predetermined depth. In Examples 6 to 9 and Comparative Example 4, the thicknesses of the resist patterns before blasting were 50 pin, and the diameters of the resist patterns before blasting were approximately 500 μm.

Table 3 shows the particle sizes of the shot media, the number of times of processing, thicknesses and diameters of the resist patterns before processing, thicknesses of the resist patterns after processing, diameters of the top surfaces of the protrusions, and approximate expressions of the processed shapes of Examples 6 to 9 and Comparative Example 4.

TABLE 3

| | | COMPARATIVE | | | | |
|---|---|---|---|---|---|---|
| | | EXAMPLE 4 | EXAMPLE 6 | EXAMPLE 7 | EXAMPLE 8 | EXAMPLE 9 |
| | PARTICLE SIZE OF | #220 | #400 | #600 | #1200 | #1500 |
| | SHOT MEDIA | (≈70 μm) | (≈38 μm) | (≈25 μm) | (≈13 μm) | (≈10 μm) |
| | (AVERAGE PARTICLE | | | | | |
| | DIAMETER) | | | | | |
| | NUMBER OF TIMES | 1 | 2 | 3 | 4 | 6 |
| | OF PROCESSING | | | | | |
| BEFORE | THICKNESS OF | 50 | 50 | 50 | 50 | 50 |
| PROCESSING | RESIST PATTERN [μm] | | | | | |
| | DIAMETER OF | 503 | 505 | 504 | 503 | 501 |
| | RESIST PATTERN [μm] | | | | | |
| AFTER | THICKNESS OF | 40 | 42 | 43 | 45 | 46 |
| PROCESSING | RESIST PATTERN [μm] | | | | | |
| | DIAMETER OF TOP | 495 | 496 | 496 | 499 | 499 |
| | SURFACE OF | | | | | |
| | PROTRUSION [μm] | | | | | |
| | PROCESSED SHAPE | z = 0.005x² − 0.04x | z = 0.05x² − 0.05x | z = 0.123x² − 0.13x | z = 0.185x² − 0.73x | z = 0.18x² − 0.955x |
| | (APPROXIMATE | | | | | |
| | EXPRESSION) | | | | | |

In Comparative Example 4, since the average particle diameter of the shot media MD was large, it is considered that the shot media MD did not sufficiently reach the corner portion formed by the surface 101a and the protrusion 102. For this reason, the processed shape was a tapered shape in which the diameter increases from the top surface 102a toward the surface 101a. On the other hand, in Examples 6 to 9, since the average particle diameter of the shot media MD was small, it is considered that the shot media MD sufficiently reached the corner portion formed by the surface 101a and the protrusion 102. Therefore, the processed shape was a shape in which the protrusion 102 rises sharply in the Z-axis direction from the surface 101a.

What is claimed is:

1. A method for manufacturing a component made of a hard brittle material, the method comprising:
a step of preparing a base material made of a hard brittle material; and
a step of embossing the base material,
wherein a protrusion protruding in a first direction and a bottom surface surrounding the protrusion are formed on the base material by the embossing,
wherein the bottom surface extends in a plane defined by a second direction intersecting the first direction and a third direction intersecting the first direction and the second direction,
wherein the bottom surface and a side surface of the protrusion continuous with the bottom surface satisfy a relationship of z=Ax²−Bx in a cross section defined by the first direction and the second direction when the first direction is represented by z and the second direction is represented by x, and
wherein A is 0.005 to 0.200 and B is 0.050 to 0.955.

2. The method for manufacturing a component made of a hard brittle material according to claim 1,
wherein the step of embossing comprises a step of forming a mask pattern on the base material and a step of blasting the base material on which the mask pattern is formed.

3. The method for manufacturing a component made of a hard brittle material according to claim 2,
wherein a constituent material of the mask pattern is an acrylic urethane resin.

4. The method for manufacturing a component made of a hard brittle material according to claim 2,
wherein an injection speed of shot media used in the blasting is 100 meters per second or more.

5. The method for manufacturing a component made of a hard brittle material according to claim 3,
wherein an injection speed of shot media used in the blasting is 100 meters per second or more.

6. The method for manufacturing a component made of a hard brittle material according to claim 2,
wherein a particle diameter of shot media used for the blasting is 38 μm or less.

7. The method for manufacturing a component made of a hard brittle material according to claim 3,
wherein a particle diameter of shot media used for the blasting is 38 μm or less.

8. The method for manufacturing a component made of a hard brittle material according to claim 4,
wherein a particle diameter of shot media used for the blasting is 38 μm or less.

9. The method for manufacturing a component made of a hard brittle material according to claim 5,
wherein a particle diameter of shot media used for the blasting is 38 μm or less.

10. A component made of a hard brittle material, comprising:
a base having a flat plate shape; and
a protrusion protruding from one surface of the base in a first direction,
wherein the one surface extends in a plane defined by a second direction intersecting the first direction and a third direction intersecting the first direction and the second direction,
wherein the one surface and a side surface of the protrusion continuous with the one surface satisfy a relationship of z=Ax²−Bx in a cross section defined by the first direction and the second direction when the first direction is represented by z and the second direction is represented by x, and
wherein A is 0.005 to 0.200 and B is 0.050 to 0.955.
